(19) United States
(12) Patent Application Publication
(10) Pub. No.: US 2026/0096380 A1
(43) Pub. Date: Apr. 2, 2026

(54) SUBSTRATE PROCESSING APPARATUS

(71) Applicant: SHIBAURA MECHATRONICS CORPORATION, Yokohama-shi (JP)

(72) Inventors: Kosei Yanachi, Yokohama-shi (JP); Keigo Oomori, Yokohama-shi (JP)

(73) Assignee: SHIBAURA MECHATRONICS CORPORATION, Yokohama-shi (JP)

(21) Appl. No.: 19/340,985

(22) Filed: Sep. 26, 2025

(30) Foreign Application Priority Data
Sep. 30, 2024 (JP) 2024-170333

(51) Int. Cl. H01L 21/67

(52) U.S. Cl. CPC H10P 72/0414

(57) ABSTRACT

A substrate processing apparatus includes: a processing chamber configured to define a space for processing a substrate; a rotary holding part configured to hold and rotate the substrate; a processing liquid supply part configured to supply a processing liquid to the substrate held by the rotary holding part; an exhaust part having an exhaust path for discharging a gas discharged from an interior of the processing chamber to an outside; and a removal part including a nozzle, which is arranged inside the exhaust path and configured to inject a mist-like cleaning liquid.

### CROSS-REFERENCE TO RELATED APPLICATION

This application is based upon and claims the benefit of priority from Japanese Patent Application No. 2024-170333, filed on September 30, 2024, the entire contents of which are incorporated herein by reference.

### TECHNICAL FIELD

The present disclosure relates to a substrate processing apparatus.

### BACKGROUND

A single-substrate-type substrate processing apparatus is an apparatus that processes substrates, such as semiconductor wafers, one by one by supplying a processing liquid to the surfaces of the substrates while rotating the substrates. Compared to a batch-type substrate processing apparatus in which multiple substrates are immersed in a processing liquid at the same time, the single-substrate-type substrate processing apparatus has the advantage of being able to finely adjust processing conditions according to differences in the thicknesses of films formed on the respective substrates.

The processing liquid supplied to a substrate is, for example, a sulfuric acid-hydrogen peroxide mixture (SPM), which is a mixture of a sulfuric acid solution and a hydrogen peroxide solution.

When the SPM is supplied to a substrate, the reaction between sulfuric acid and hydrogen peroxide may generate an atmosphere containing numerous fine particles called fumes. In order to keep clean the inside of a processing chamber in which a substrate is processed, the substrate processing apparatus introduces a clean gas into the processing chamber and evacuates the inside of the processing chamber.

The exhaust gas discharged from the substrate processing apparatus by evacuating the inside of the processing chamber is sent to, for example, a detoxification system (exhaust gas treatment device) installed in a factory in which the substrate processing apparatus is installed, and is made harmless by the detoxification system before being released into the external environment. However, if the exhaust gas discharged from the substrate processing apparatus contains fine particles, it will put a strain on the detoxification system.

### SUMMARY

Some embodiments of the present disclosure provide a substrate processing apparatus capable of suppressing the inclusion of fine particles in a gas discharged from a processing chamber for processing a substrate to the outside of the substrate processing apparatus.

According to one embodiment of the present disclosure, there is provided a substrate processing apparatus including: a processing chamber configured to define a space for processing a substrate; a rotary holding part configured to hold and rotate the substrate; a processing liquid supply part configured to supply a processing liquid to the substrate held by the rotary holding part; an exhaust part having an exhaust path for discharging a gas discharged from an interior of the processing chamber to an outside; and a removal part including a nozzle, which is arranged inside the exhaust path and configured to inject a mist-like cleaning liquid.

### BRIEF DESCRIPTION OF DRAWINGS

The accompanying drawings, which are incorporated in and constitute a part of the specification, illustrate embodiments of the present disclosure.

FIG. 1 is an axial sectional view schematically showing the configuration of a substrate processing apparatus according to an embodiment.

FIG. 2 is a plan view schematically showing the configuration of the substrate processing apparatus taken along line A-A in FIG. 1.

FIG. 3 is a partially enlarged axial sectional view of the substrate processing apparatus according to the embodiment.

FIG. 4 is an axial sectional view of the substrate processing apparatus taken along line B-B in FIG. 1.

FIG. 5 is a view illustrating the state of a mist-like cleaning liquid supplied to an exhaust path.

FIG. 6 is a flowchart showing the operation of the substrate processing apparatus according to the embodiment.

FIG. 7 is a view schematically showing an example of the substrate processing apparatus equipped with a heating part.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, a substrate processing apparatus according to an embodiment of the present disclosure will be described with reference to the drawings. In the specification and claims of this application, "up" refers to the direction in which the installation surface of the substrate processing apparatus (e.g., the factory floor) faces when the substrate processing apparatus is installed in a state in which it can be used normally, and "down" refers to the opposite direction to "up." Furthermore, when the center of the substrate processing apparatus in a plan view is used as a reference, the direction away from the center is referred to as "outside," and the direction toward the center is referred to as "inside."

As an example of the substrate processing apparatus according to the embodiment of the present disclosure, a substrate processing apparatus will be described that supplies a mixed liquid (SPM, sulfuric acid-hydrogen peroxide mixture) of a sulfuric acid (H₂SO₄) solution and a hydrogen peroxide (H₂O₂) solution as a processing liquid to a semiconductor wafer having a resist formed on its surface to remove at least a portion of the resist. However, the type of substrate to be processed and the type of processing liquid are not limited thereto.

### Overview

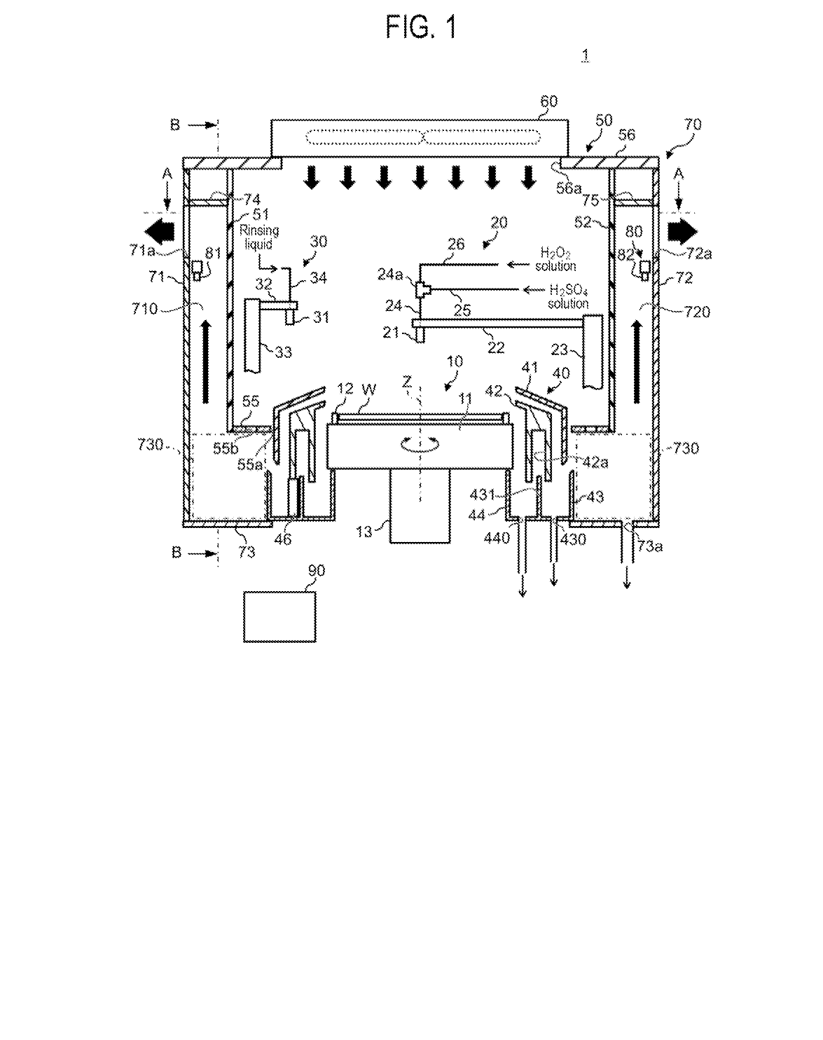

As shown in FIG. 1, the substrate processing apparatus 1 of this embodiment processes a substrate W loaded into a processing chamber 50 by supplying a processing liquid to the substrate W from a processing liquid supply part 20 while holding and rotating the substrate W with a rotary holding part 10. A clean gas is supplied into the processing chamber 50 from a gas supply part 60. In addition, the interior of the processing chamber 50 is also evacuated by an exhaust part 70.

A mist-like cleaning liquid is supplied from a removal part 80 to the inside of exhaust paths (first exhaust path 710 and second exhaust path 720) of the exhaust part 70. Floating particles generated by the supply of the processing liquid and contained in the exhaust gas from the inside of the processing chamber 50 are captured by the mist-like cleaning liquid and discharged from a discharge port 73a. This makes it possible to remove the particles from the exhaust gas and to prevent the particles from being contained in the gas discharged to the outside from the substrate processing apparatus 1.

### Configuration of Substrate Processing Apparatus 1

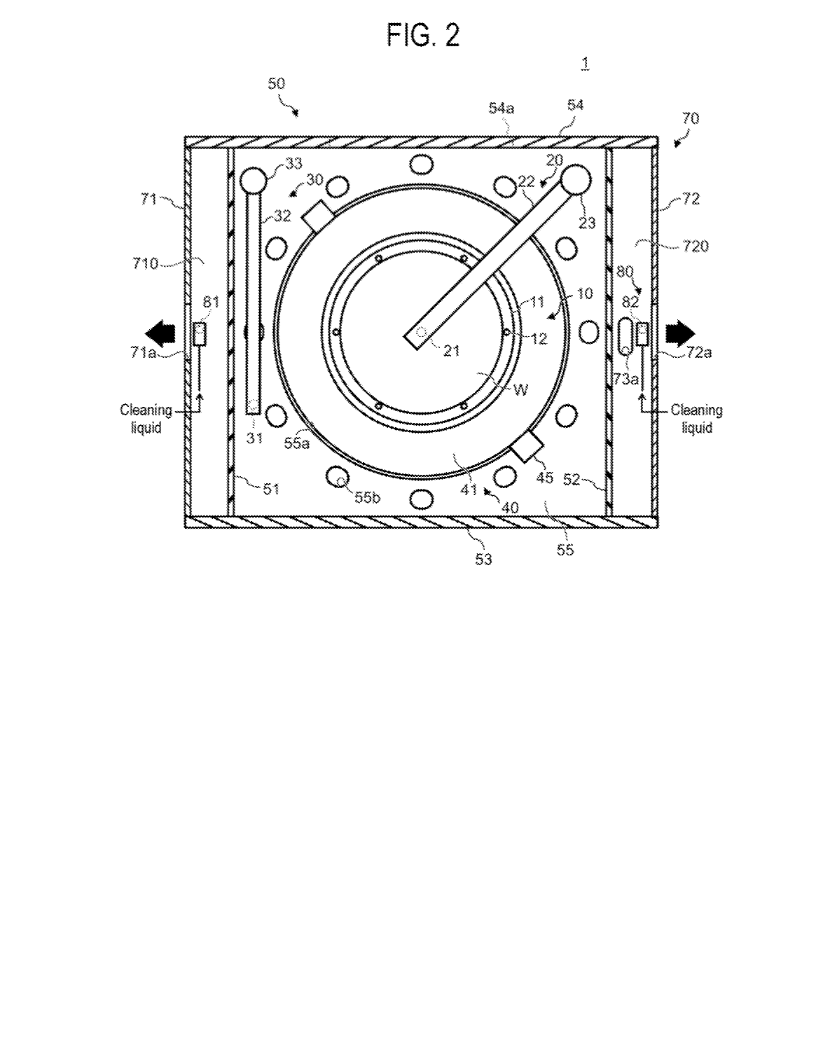

The configuration of the substrate processing apparatus 1 will be described with reference to FIGS. 1 and 2. FIG. 1 is an axial sectional view schematically illustrating the configuration of the substrate processing apparatus 1. FIG. 2 is a plan view schematically illustrating the configuration of the substrate processing apparatus 1 taken along line A-A in FIG. 1.

The substrate processing apparatus 1 includes a rotary holding part 10, a processing liquid supply part 20, a rinsing liquid supply part 30, a collection part 40, a processing chamber 50, a gas supply part 60, an exhaust part 70, a removal part 80, and a control device 90.

### Rotary Holding Part 10

The rotary holding part 10 holds a substrate W and rotates it around an axis Z. The rotary holding part 10 includes a rotary table 11, a holder 12, and a rotational drive part 13. The rotary table 11 is positioned approximately at the center of the processing chamber 50. The upper surface of the rotary table 11 is formed into a circular surface larger than the substrate W and faces the substrate W with a gap left therebetween.

The holder 12 holds the substrate W horizontally on the rotary table 11 at a distance from the upper surface of the rotary table 11. A plurality of holders 12 is provided on the upper surface of the rotary table 11 at predetermined intervals along the outer peripheral edge of the substrate W. In this embodiment, six holders 12 are provided as shown in FIG. 2. The holders 12 are movable by an opening/closing mechanism (not shown) between a holding position in which the holders 12 contact the outer peripheral edge of the substrate W to hold the substrate W, and a release position in which the holders 12 move away from the outer peripheral edge of the substrate W to release the substrate W. The center of the substrate W held by the holders 12 at the holding position is positioned to coincide with the axis Z.

The rotational drive part 13 is a drive mechanism that rotates the rotary table 11. The rotational drive part 13 includes a rotary shaft connected to the center of the rotary table 11 and a motor that rotates the rotary shaft. The rotational drive part 13 rotates the rotary table 11 about the axis Z via the rotary shaft by driving the motor. When the rotary table 11 rotates, the substrate W held by the holder 12 rotates about the axis Z.

### Processing Liquid Supply Part 20

The processing liquid supply part 20 supplies a processing liquid to the substrate W held by the holders 12. In this embodiment, the processing liquid supply part 20 supplies a mixture (SPM) of a sulfuric acid (H₂SO₄) solution and a hydrogen peroxide (H₂O₂) solution to the substrate W as the processing liquid. The processing liquid supply part 20 includes a nozzle 21, a swing arm 22, a swing mechanism 23, a processing liquid supply pipe 24, a sulfuric acid supply pipe 25, and a hydrogen peroxide solution supply pipe 26.

The nozzle 21 (processing liquid nozzle) is attached to the swing arm 22 and is arranged to be swingable in a horizontal plane above the rotary table 11 by the swing mechanism 23. The nozzle 21 injects the processing liquid toward the substrate W while facing the vicinity of the center of the substrate W held by the holders 12.

The swing arm 22 is a member that holds the nozzle 21. The swing arm 22 is formed in a rod shape, and the nozzle 21 is attached to one end of the swing arm 22. The other end of the swing arm 22 opposite the nozzle 21 is connected to the swing mechanism 23. The swing arm 22 is supported by the swing mechanism 23 so as to extend in the horizontal direction. The swing mechanism 23 supports the swing arm 22 and swings the swing arm 22 in a horizontal plane around the swing mechanism 23 as a swing axis. The swing mechanism 23 moves the nozzle 21 between an injection position facing the vicinity of the center of the substrate W held by the holders 12 and a retracted position that is a position outward from the rotary table 11.

The processing liquid supply pipe 24 is a pipe for supplying the processing liquid to the nozzle 21. The tip end of the processing liquid supply pipe 24 is connected to the nozzle 21. The rear end of the processing liquid supply pipe 24 is connected to the sulfuric acid supply pipe 25 and the hydrogen peroxide solution supply pipe 26 via a connection portion 24a.

The sulfuric acid supply pipe 25 is a pipe for supplying a sulfuric acid (H₂SO₄) solution sent from a sulfuric acid solution supply source (e.g., a tank) (not shown) provided outside the substrate processing apparatus 1 to the processing liquid supply pipe 24. The hydrogen peroxide solution supply pipe 26 is a pipe for supplying a hydrogen peroxide (H₂O₂) solution sent from a hydrogen peroxide solution supply source (e.g., a tank) (not shown) provided outside the substrate processing apparatus 1 to the processing liquid supply pipe 24. The sulfuric acid solution supplied by the processing liquid supply pipe 24 and the hydrogen peroxide solution supplied by the hydrogen peroxide solution supply pipe 26 join at the connection portion 24a to form a mixed solution (SPM), which is supplied to the processing liquid supply pipe 24. The mixed solution then passes through the processing liquid supply pipe 24 and is injected from the nozzle 21.

As shown in FIG. 1, in this embodiment, the connection portion 24a in which the sulfuric acid solution and the hydrogen peroxide solution are mixed is disposed inside the processing chamber 50. This makes it possible to shorten the time from when the SPM is generated to when the SPM is injected from the nozzle 21. Since the time from when the SPM is generated to when the SPM is injected from the nozzle 21 is short, it is possible to supply the SPM in a highly active state to the substrate W.

### Rinsing Liquid Supply Part 30

The rinsing liquid supply part 30 supplies a rinsing liquid to the substrate W held by the holders 12. In this embodiment, the rinsing liquid supply part 30 supplies deionized water as the rinsing liquid to the substrate W. The rinsing liquid supply part 30 includes a nozzle 31, a swing arm 32, a swing mechanism 33, and a rinsing liquid supply pipe 34.

The nozzle 31 (rinsing liquid nozzle) is attached to the swing arm 32 and is arranged to be swingable in a horizontal plane above the rotary table 11 by the swing mechanism 33. The nozzle 31 injects the rinsing liquid toward the substrate W while facing the vicinity of the center of the substrate W held by the holders 12.

The swing arm 32 is a member that holds the nozzle 31. The swing arm 32 is formed in a rod shape, and the nozzle 31 is attached to one end of the swing arm 32. The other end of the swing arm 32 opposite the nozzle 31 is connected to the swing mechanism 33. The swing arm 32 is supported by the swing mechanism 33 so as to extend in the horizontal direction. The swing mechanism 33 supports the swing arm 32 and swings the swing arm 32 in a horizontal plane around the swing mechanism 33 as a swing axis. The swing mechanism 33 moves the nozzle 31 between an injection position facing the vicinity of the center of the substrate W held by the holders 12 and a retracted position which is a position outward from the rotary table 11.

The rinsing liquid supply pipe 34 is a pipe for supplying a rinsing liquid to the nozzle 31. The tip end of the rinsing liquid supply pipe 34 is connected to the nozzle 31. The rear end of the rinsing liquid supply pipe 34 is connected to a pipe extending from a pure water production system provided in a factory in which the substrate processing apparatus 1 is installed. The rinsing liquid (pure water) sent from the pure water production system passes through the rinsing liquid supply pipe 34 and is injected from the nozzle 31.

### Collection Part 40

The collection part 40 collects the processing liquid or the rinsing liquid supplied to the substrate W and splashed from the substrate W due to the rotation of the substrate W. The collection part 40 includes a first cup 41, a second cup 42, a first liquid receiving part 43, a second liquid receiving part 44, a first lifting mechanism 45 (see FIG. 2), and a second lifting mechanism 46 (see FIG. 1).

The first cup 41 receives the processing liquid or the rinsing liquid splashed from the substrate W and drops it downward. The first cup 41 is a cylindrical body formed so that the diameter narrows at the top portion, and is provided so as to cover the periphery of the rotary table 11 using the axis Z of rotation of the rotary table 11 as a center. The processing liquid or the rinsing liquid splashed from the substrate W due to the rotation of the substrate W collides with, and is received by, the inner peripheral surface of the first cup 41, and flows downward along the inner peripheral surface.

The first cup 41 is movable between an up position and a down position by the first lifting mechanism 45. The up position is a position in which the upper end of the first cup 41 is located above the height of the substrate W held by the holders 12 and can receive the processing liquid or the rinsing liquid splashed from the substrate W. The down position is a position in which the upper end of the first cup 41 is at the same height as or lower than the height of the upper surface of the rotary table 11 and in which the substrate W can be loaded or unloaded.

The second cup 42 receives the processing liquid or the rinsing liquid splashed from the substrate W and drops it downward. The second cup 42 is a cylindrical body formed so that the diameter narrows at the top portion. The second cup 42 is provided between the rotary table 11 and the first cup 41 so as to cover the periphery of the rotary table 11 using the axis Z of rotation of the rotary table 11 as a center. The processing liquid or the rinsing liquid splashed from the substrate W due to the rotation of the substrate W collides with, and is received by, the inner peripheral surface of the second cup 42, and flows downward along the inner peripheral surface. A recess 42a is formed in a lower portion of the second cup 42. The recess 42a is open at the bottom and defines a space extending upward from the opening.

The second cup 42 is movable between an up position and a down position by the second lifting mechanism 46. The up position is a position in which the upper end of the second cup 42 is located above the height of the substrate W held by the holders 12 and in which the processing liquid or the rinsing liquid splashed from the substrate W can be received. The down position is a position in which the upper end of the second cup 42 is located below the height of the upper surface of the rotary table 11 and in which the substrate W can be loaded or unloaded. When the first cup 41 is located at the up position, the second cup can be located at the down position to allow the first cup 41 to receive the processing liquid or the rinsing liquid splashed from the substrate W. In other words, depending on the position of the second cup 42, the cup that receives the processing liquid or the rinsing liquid splashed from the substrate W can be switched between the first cup 41 and the second cup 42.

The first liquid receiving part 43 collects the processing liquid or the rinsing liquid received by the first cup 41 and falling downward. The second liquid receiving part 44 collects the processing liquid or the rinsing liquid received by the second cup 42 and falling downward. The first liquid receiving part 43 and the second liquid receiving part 44 are integrally formed and separated by a partition wall 431. The first liquid receiving part 43 is located outside the partition wall 431, and the second liquid receiving part 44 is located inside the partition wall 431.

The partition wall 431 is disposed opposite the recess 42a of the second cup 42. When the second cup 42 moves from the up position to the down position, the recess 42a is moved downward and the partition wall 431 is inserted into the recess 42a. The partition wall 431 and the recess 42a are provided without contact via a gap, allowing a gas to flow between the partition wall 431 and the recess 42a.

The first liquid receiving part 43 is a circular container that is open at the top portion. A discharge port 430 is formed in the bottom surface of the first liquid receiving part 43. The processing liquid or the rinsing liquid collected in the first liquid receiving part 43 is discharged from the discharge port 430 and is collected or discarded outside the substrate processing apparatus 1.

The second liquid receiving part 44 is a circular container that is open at the top portion. A discharge port 440 is formed in the bottom surface of the second liquid receiving part 44. The processing liquid or the rinsing liquid collected in the second liquid receiving part 44 is discharged from the discharge port 440 and is collected or discarded outside the substrate processing apparatus 1.

The first lifting mechanism 45 is connected to the first cup 41 and moves the first cup 41 in a direction parallel to the axis Z. The second lifting mechanism 46 is connected to the second cup 42 and moves the second cup 42 in a direction parallel to the axis Z. The first lifting mechanism 45 and the second lifting mechanism 46 may be, for example, a cylinder, a ball screw mechanism, or the like.

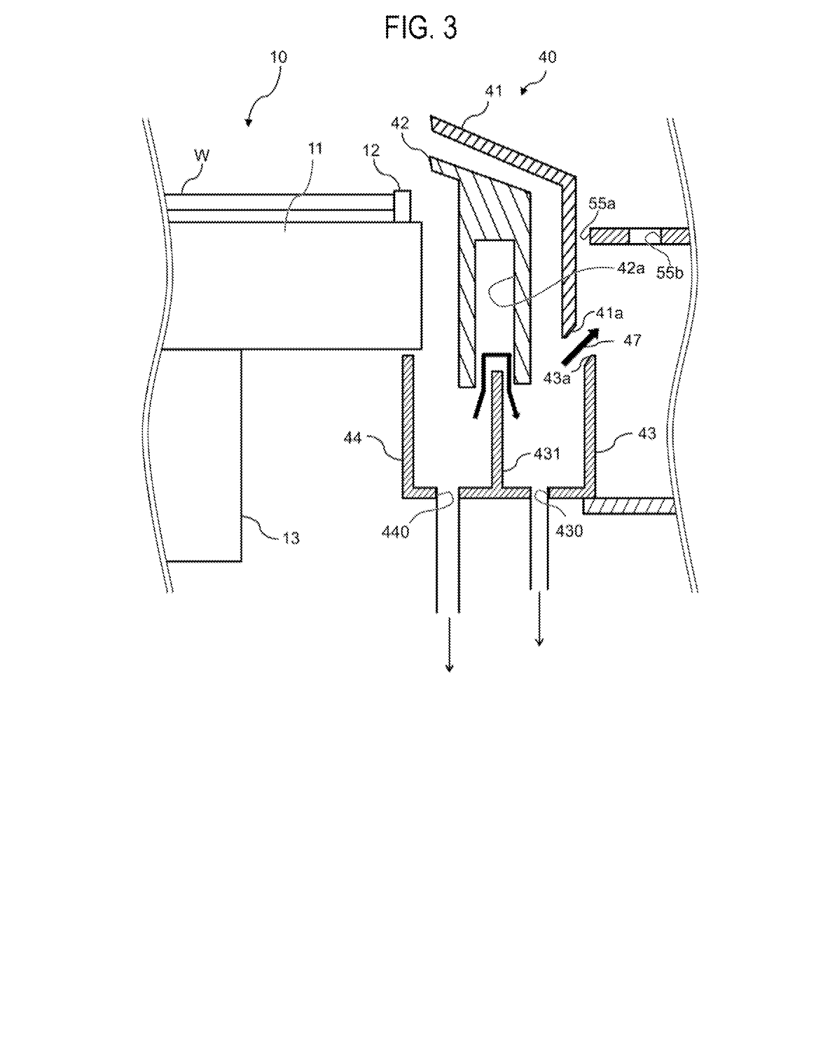

The structure of the collection part 40 will now be described in more detail with reference to FIG. 3. FIG. 3 is a partially enlarged axial sectional view of the substrate processing apparatus 1. In FIG. 3, the first cup 41 and the second cup 42 are positioned at the up position.

As shown in FIG. 3, the lower end of the first cup 41 is formed with a tapered surface 41a approaching the inside as it goes downward. Furthermore, the upper end of the outer side wall of the first liquid receiving part 43 is formed with a tapered surface 43a approaching the outside as it goes upward. In this embodiment, the tapered surface 41a and the tapered surface 43a are arranged parallel to each other. Furthermore, when the first cup 41 is at the up position, the lower end of the tapered surface 41a of the first cup 41 is positioned higher than the upper end of the tapered surface 43a of the first liquid receiving part 43.

As a result, a gas flow path 47, which is a flow path inclined to extend upward as it goes outward, is formed by the tapered surface 41a of the first cup 41 and the tapered surface 43a of the first liquid receiving part 43. The gas flow path 47 serves to connect the space inside the first cup 41 to a communication portion 730, which will be described later.

As described above, the second cup 42 is provided without contact with the partition wall 431 via a gap due to the recess 42a formed in the lower portion of the second cup 42. As a result, the space inside the second cup 42 is also in communication with the communication portion 730 via the gap, the interior of the first cup 41, and the gas flow path 47. Since the second cup 42 is provided more inward than the first cup 41, the interior of the second cup 42 is also the interior of the first cup 41. Therefore, in the following description, the internal spaces of the first cup 41 and the second cup 42 will be collectively referred to as the "space surrounded by the first cup 41."

### Processing Chamber 50

The processing chamber 50 constitutes a space (hereinafter referred to as the "processing space") in which a substrate W is loaded and processed. The processing chamber 50 includes a first side wall 51, a second side wall 52, a third side wall 53, a fourth side wall 54, an intermediate plate 55, and a top plate 56.

Each of the first side wall 51, the second side wall 52, the third side wall 53, and the fourth side wall 54 is a substantially rectangular plate-like body with its surfaces parallel to the up-down direction. The vertical lengths of the third side wall 53 and the fourth side wall 54 are longer than the vertical lengths of the first side wall 51 and the second side wall 52.

The first side wall 51 and the second side wall 52 are provided opposite each other and spaced apart in the left-right direction shown in FIG. 2. The third side wall 53 and the fourth side wall 54 are provided opposite each other and spaced apart in the up-down direction shown in FIG. 2. One of the ends of the first side wall 51 extending in the up-down direction shown in FIG. 2 is connected to the third side wall 53, and the other end of the first side wall 51 extending in the up-down direction shown in FIG. 2 is connected to the fourth side wall 54. Furthermore, one of the ends of the second side wall 52 extending in the up-down direction shown in FIG. 2 is connected to the third side wall 53, and the other end of the second side wall 52 extending in the up-down direction shown in FIG. 2 is connected to the fourth side wall 54. As a result, the processing space is surrounded by the first side wall 51, the second side wall 52, the third side wall 53, and the fourth side wall 54.

The fourth side wall 54 is formed with a loading/unloading port 54a (see FIG. 2), which is an opening for loading and unloading the substrate W into and out of the substrate processing apparatus 1. A shutter (not shown) is provided at the loading/unloading port 54a, and the loading/unloading port 54a is configured to be openable and closable by the shutter.

As shown in FIG. 2, a portion in which the end of the first side wall 51 and the end of the second side wall 52 are connected to the third side wall 53 is located more inward than ends of the third side wall 53 in a plan view. Similarly, a portion in which the end of the first side wall 51 and the end of the second side wall 52 are connected to the fourth side wall 54 is located more inward than ends of the fourth side wall 54.

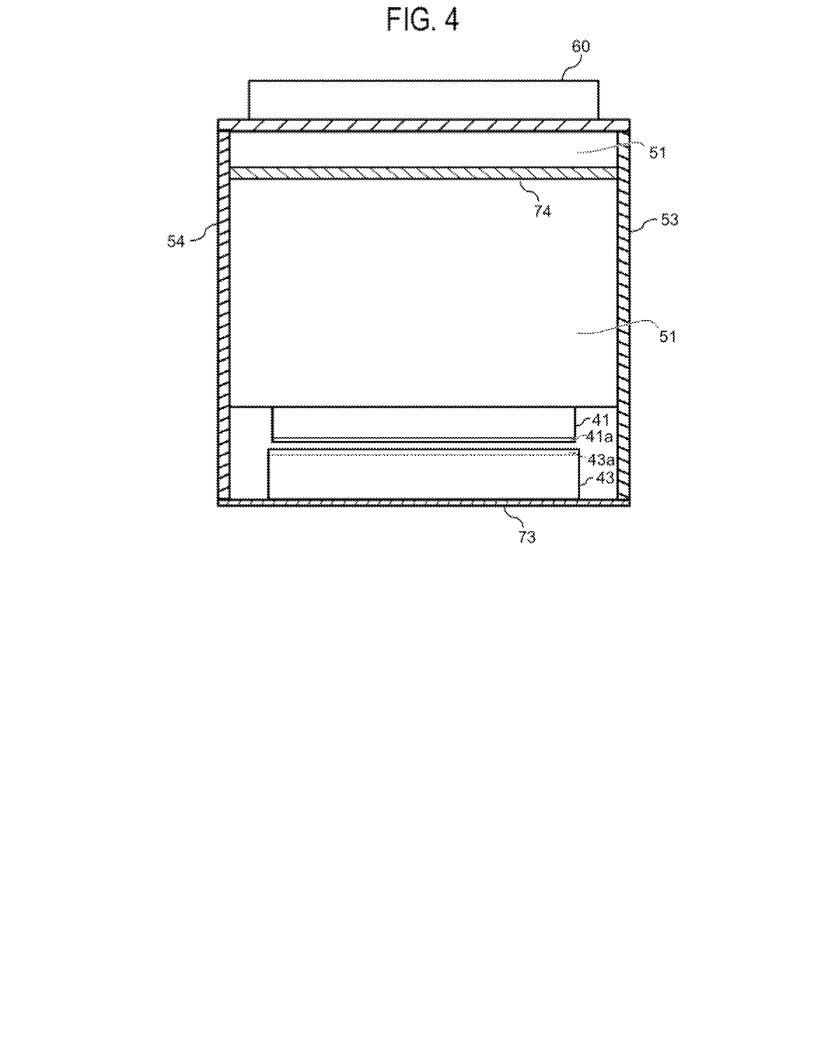

As shown in FIG. 4, the first side wall 51 is connected so that an upper end of the first side wall 51 is positioned at the same position as upper ends of the third side wall 53 and the fourth side wall 54. FIG. 4 is an axial sectional view of the substrate processing apparatus 1 taken along line B-B in FIG. 1. In FIG. 4, the first cup 41 is at the up position. The rotary holding part 10, the second cup 42, the processing liquid supply part 20 (swing mechanism 23), and the rinsing liquid supply part 30 (swing mechanism 33) are not shown. Similarly to the first side wall 51, the second side wall 52 is also connected so that an upper end of the second side wall 52 is positioned at the same position as the upper ends of the third side wall 53 and the fourth side wall 54.

The third side wall 53 and the fourth side wall 54 also constitute portions of the exhaust part 70, which will be described later. More specifically, in the third side wall 53 and the fourth side wall 54, portions that are outside the position in which the first side wall 51 and the second side wall 52 are connected in a plan view (see FIGS. 1 and 2) also constitute portions of the exhaust part 70, which will be described later. Furthermore, in the third side wall 53 and the fourth side wall 54, the portions that are below the lower ends of the first side wall 51 and the second side wall 52 (see FIG. 4) also constitute portions of the exhaust part 70, which will be described later. In addition, the first side wall 51 and the second side wall 52 also constitute portions of the exhaust part 70, which will be described later.

Returning to FIGS. 1 and 2, the intermediate plate 55 is a plate-like body provided to close the bottom of the space surrounded by the first side wall 51, the second side wall 52, the third side wall 53, and the fourth side wall 54. The intermediate plate 55 is connected to the lower ends of the first side wall 51 and the second side wall 52. A mounting hole 55a, which is a through-hole having a shape corresponding to the outer shape of the first cup 41, is formed at the central portion of the intermediate plate 55. The first cup 41 is inserted into the mounting hole 55a. Furthermore, the intermediate plate 55 is formed with a plurality of through-holes 55b in addition to the mounting hole 55a. In this embodiment, as shown in FIG. 2, twelve through-holes 55b are formed around the mounting hole 55a. The through-holes 55b are used to connect the processing space to the exhaust part 70, which will be described later.

The top plate 56 is a plate-like body provided to close the top of the space surrounded by the first side wall 51, the second side wall 52, the third side wall 53, and the fourth side wall 54. An opening 56a, which is a through-hole, is formed at the central portion of the top plate 56. A gas supply part 60 is provided above the top plate 56. The gas supplied by the gas supply part 60 is introduced into the processing chamber 50 through the opening 56a.

### Gas Supply Part 60

The gas supply unit 60 supplies a clean gas into the processing chamber 50. The gas supply part 60 is, for example, a fan filter unit (FFU) that purifies an air in a factory (clean room) in which the substrate processing apparatus 1 is installed and supplies the air to the processing chamber 50. The FFU includes a fan that introduces the air from the factory and sends the air into the processing chamber 50, and a filter (e.g., a HEPA filter (High Efficiency Particulate Air filter) or a ULPA filter (Ultra Low Penetration Air filter)) that purifies the introduced air. The air introduced by the fan is purified by passing through the filter. The gas supply part 60 supplies the clean gas into the processing chamber 50 through the opening 56a, thereby creating a downflow within the processing chamber 50.

### Exhaust Part 70

The exhaust part 70 evacuates the interior of the processing space. A duct leading to an exhaust gas treatment facility (detoxification facility) installed in a factory in which the substrate processing apparatus 1 is installed is connected to the exhaust part 70. The gas exhausted from the processing space by the exhaust part 70 is sent to the exhaust gas treatment facility via the duct.

The exhaust part 70 includes the first exhaust path 710, a second exhaust path 720, and a communication portion 730. The first exhaust path 710 is formed on the outer side of the first side wall 51 (on the left side in FIGS. 1 and 2). The second exhaust path 720 is formed on the outer side of the second side wall 52 (on the right side in FIGS. 1 and 2).

A bottom plate 73 is provided below the intermediate plate 55 and parallel to the intermediate plate 55 with a gap left therebetween. A through-hole having a shape corresponding to the outer shape of the first liquid receiving part 43 is provided at the central portion of the bottom plate 73 so that the bottom plate 73 can be connected to the lower end of the first liquid receiving part 43 via the through-hole. The bottom plate 73 also has a discharge port 73a for discharging the cleaning liquid injected from the removal part 80, which will be described later.

The space below the intermediate plate 55 and outside the collection part 40 functions as a communication portion 730. The communication portion 730 brings the processing space into communication with the first exhaust path 710 and the second exhaust path 720.

A part of the gas (downflow) supplied to the processing space by the gas supply part 60 flows toward the upper surface of the substrate W held by the holders 12 and into the space surrounded by the first cup 41. The space surrounded by the first cup 41 is connected to the communication portion 730 by the gas flow path 47 described above. This allows the gas that has flowed into the space surrounded by the first cup 41 to flow through the gas flow path 47 and into the communication portion 730. Furthermore, a part of the gas introduced into the processing space by the gas supply part 60 flows toward the outside of the first cup 41. The gas that has flowed toward the outside of the first cup 41 can flow into the communication portion 730 through the through-holes 55b formed in the intermediate plate 55. In this way, the processing space and the communication portion 730 are connected by the gas flow path 47 or the through-holes 55b to allow the gas to pass through.

A first outer wall 71 is provided outside the first side wall 51 parallel to the first side wall 51 and spaced apart from the first side wall 51. The first outer wall 71 is a substantially rectangular plate-like body. An upper end of the first outer wall 71 is connected to an end of the top plate 56, and a lower end of the first outer wall 71 is connected to an end of the bottom plate 73. One of the ends of the first outer wall 71 extending in the up-down direction shown in FIG. 2 is connected to an end of the third side wall 53, and the other end of the first outer wall 71 extending in the up-down direction shown in FIG. 2 is connected to an end of the fourth side wall 54.

A first exhaust port 71a, which is a through-hole, is formed in the first outer wall 71. The first exhaust port 71a brings the first exhaust path 710 into communication with the outside of the substrate processing apparatus 1. In this embodiment, the first exhaust port 71a is formed above the center of the first outer wall 71 in the up-down direction, and is formed at the center of the first outer wall 71 in a plan view. A duct leading to the exhaust gas processing facility is connected to the first exhaust port 71a.

With this configuration, the space surrounded by the first side wall 51, the first outer wall 71, the third side wall 53, and the fourth side wall 54 functions as the first exhaust path 710. The first exhaust path 710 is a path for discharging the gas discharged from the processing space to the outside of the substrate processing apparatus 1. The first exhaust path 710 communicates with the communication portion 730 at its lower portion. The gas discharged from the interior of the processing space flows into the first exhaust path 710 via the communication portion 730, and the inflowing gas is discharged from the first exhaust port 71a. That is, in the first exhaust path 710, the exhaust gas from the processing space flows from bottom to top. A cover 74 is installed in the first exhaust path 710 above the position of the first exhaust port 71a to prevent the gas from staying above the position in which the first exhaust port 71a is formed.

A second outer wall 72 is provided outside the second side wall 52 parallel to the second side wall 52 and spaced apart from the second side wall 52. The second outer wall 72 is a generally rectangular plate-like body. An upper end of the second outer wall 72 is connected to an end of the top plate 56, and a lower end of the second outer wall 72 is connected to an end of the bottom plate 73. One of the ends of the second outer wall 72 extending in the up-down direction shown in FIG. 2 is connected to an end of the third side wall 53, and the other of the ends of the second outer wall 72 extending in the up-down direction shown in FIG. 2 is connected to an end of the fourth side wall 54. That is, the outer shape of the substrate processing apparatus 1 in a plan view is defined by the first outer wall 71, the second outer wall 72, the third side wall 53, and the fourth side wall 54.

A second exhaust port 72a, which is a through-hole, is formed in the second outer wall 72. The second exhaust port 72a brings the second exhaust path 720 into communication with the outside of the substrate processing apparatus 1. In this embodiment, the second exhaust port 72a is formed above the center of the second outer wall 72 in the up-down direction, and is formed at the center of the second outer wall 72 in a plan view. A duct leading to the exhaust gas treatment facility is connected to the second exhaust port 72a.

With this configuration, the space surrounded by the second side wall 52, the second outer wall 72, the third side wall 53 and the fourth side wall 54 functions as the second exhaust path 720. The second exhaust path 720 is a path for discharging the gas discharged from the processing space to the outside of the substrate processing apparatus 1. The second exhaust path 720 communicates with the communication portion 730 at its lower portion. The gas discharged from the interior of the processing space flows into the second exhaust path 720 via the communication portion 730, and the inflowing gas is discharged from the second exhaust port 72a. That is, in the second exhaust path 720, the exhaust gas from the processing space flows from bottom to top. A cover 75 is installed in the second exhaust path 720 above the position of the second exhaust port 72a to prevent the gas from staying above the position in which the second exhaust port 72a is formed.

### Removal Part 80

The removal part 80 supplies a mist-like cleaning liquid to the first exhaust path 710 and the second exhaust path 720. The removal part 80 includes a first nozzle 81 and a second nozzle 82.

The first nozzle 81 is a nozzle that injects a mist-like cleaning liquid into the first exhaust path 710. The first nozzle 81 is provided inside the first exhaust path 710 and below the first exhaust port 71a, so that the injection direction faces downward.

In this embodiment, as shown in FIG. 2, the position of the first nozzle 81 in the direction in which the first outer wall 71 extends in a plan view (in the up-down direction in FIG. 2) is the center inside the first exhaust path 710. That is, the center of the first exhaust port 71a and the center of the first nozzle 81 are provided at the same position in the direction in which the first outer wall 71 extends in a plan view. Furthermore, in the direction perpendicular to the direction in which the first outer wall 71 extends in a plan view (in the left-right direction in FIG. 2), the first nozzle 81 is provided at a position in which a distance between the first outer wall 71 and the first nozzle 81 is shorter than a distance between the first side wall 51 and the first nozzle 81. In this manner, the first nozzle 81 is provided near the first exhaust port 71a. It is preferable that the position of the first nozzle 81 in the up-down direction is lower than the first exhaust port 71a and higher than the center inside the first exhaust path 710 (the space from the connection portion with the communication portion 730 to the cover 74).

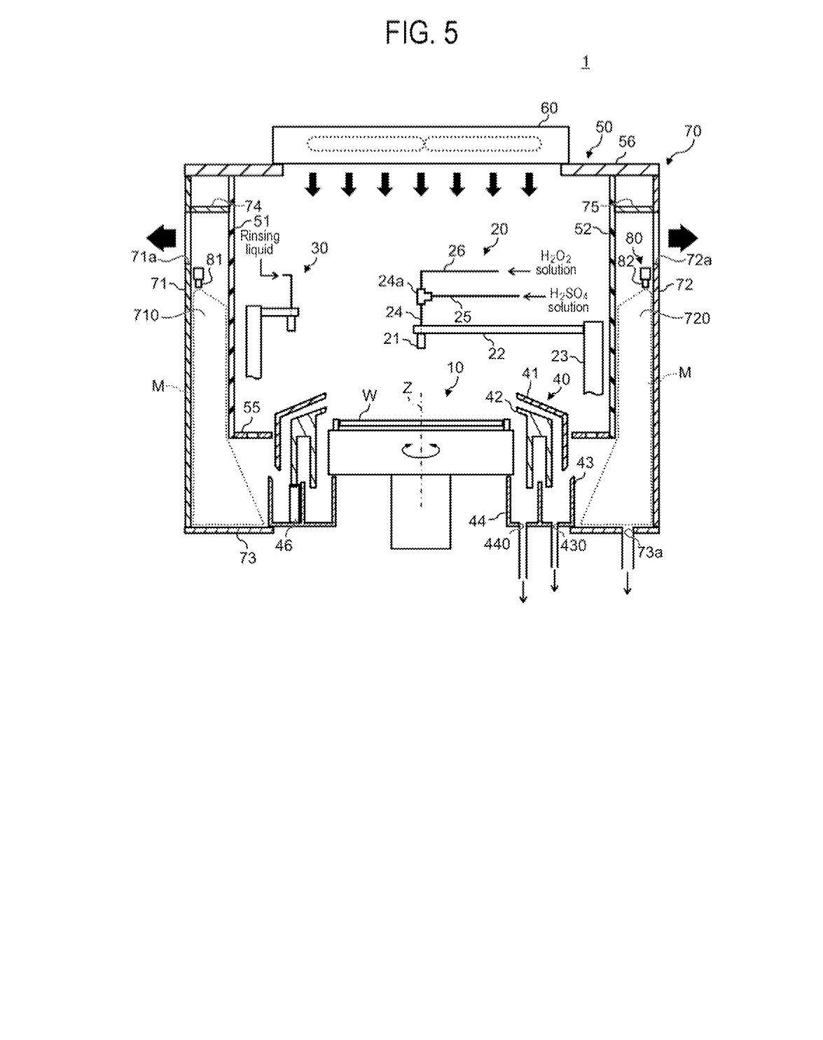

The first nozzle 81 is connected to a cleaning liquid supply source (not shown) to inject the cleaning liquid supplied from the cleaning liquid supply source. In this embodiment, the first nozzle 81 is connected to a pipe extending from a pure water production system provided in a factory in which the substrate processing apparatus 1 is installed, to inject pure water as the cleaning liquid. The cleaning liquid injected from the first nozzle 81 is in the form of mist and is diffused such that the diffusion is in a circular cone shape as shown in FIG. 5. That is, the first nozzle 81 is a so-called full cone type spray nozzle. When the cleaning liquid is injected from the first nozzle 81, the mist-like cleaning liquid is supplied to a region below the first exhaust port 71a in the first exhaust path 710. The temperature of the cleaning liquid injected from the first nozzle 81 is, for example, the room temperature.

FIG. 5 is a diagram illustrating the state of the mist-like cleaning liquid supplied to the exhaust path. In FIG. 5, the region M to which the mist-like cleaning liquid is supplied is indicated by a dotted line. As shown in FIG. 5, the spray pattern of the cleaning liquid injected from the first nozzle 81 is set so as to come into contact with at least a portion of the first side wall 51 and a portion of the first outer wall 71.

The second nozzle 82 is a nozzle that injects a mist-like cleaning liquid into the second exhaust path 720. The second nozzle 82 is provided inside the second exhaust path 720 at a position lower than the second exhaust port 72a, so that the injection direction faces downward.

In this embodiment, as shown in FIG. 2, the position of the second nozzle 82 in the direction in which the second outer wall 72 extends in a plan view (in the up-down direction in FIG. 2) is the center inside the second exhaust path 720. That is, the center of the second exhaust port 72a and the center of the second nozzle 82 are provided at the same position in the direction in which the second outer wall 72 extends in a plan view. Furthermore, in the direction perpendicular to the direction in which the second outer wall 72 extends in a plan view (in the left-right direction in FIG. 2), the second nozzle 82 is provided at a position in which a distance between the second outer wall 72 and the second nozzle 82 is shorter than a distance between the second side wall 52 and the second nozzle 82. In this manner, the second nozzle 82 is provided near the second exhaust port 72a. It is preferable that the position of the second nozzle 82 in the up-down direction is lower than the second exhaust port 72a and higher than the center inside the second exhaust path 720 (the space from the connection portion with the communication portion 730 to the cover 75).

The second nozzle 82 is connected to a cleaning liquid supply source (not shown) to inject the cleaning liquid supplied from the cleaning liquid supply source. In this embodiment, the second nozzle 82 is connected to a pipe extending from a pure water production system provided in a factory in which the substrate processing apparatus 1 is installed, to inject pure water as the cleaning liquid. The cleaning liquid injected from the second nozzle 82 is in the form of mist and is diffused in a circular cone shape. That is, the second nozzle 82 is a so-called full cone type spray nozzle. For example, the second nozzle 82 may be a nozzle similar to the first nozzle 81. When the cleaning liquid is injected from the second nozzle 82, the mist-like cleaning liquid is supplied to a region below the second exhaust port 72a in the second exhaust path 720. The temperature of the cleaning liquid injected from the second nozzle 82 is, for example, the room temperature.

As shown in FIG. 5, the spray pattern of the cleaning liquid injected from the second nozzle 82 is set to contact at least a portion of the second side wall 52 and a portion of the second outer wall 72.

### Control Device 90

The control device 90 controls the operation of the substrate processing apparatus 1. The control device 90 includes a processor that executes a program for processing a substrate W, a memory that stores various information such as programs and operating conditions, and a drive circuit that drives each part. Specifically, the control device 90 controls the rotary holding part 10, the processing liquid supply part 20, the rinsing liquid supply part 30, the collection part 40, the gas supply part 60, the removal part 80, and the like.

### Operation of Substrate Processing Apparatus 1

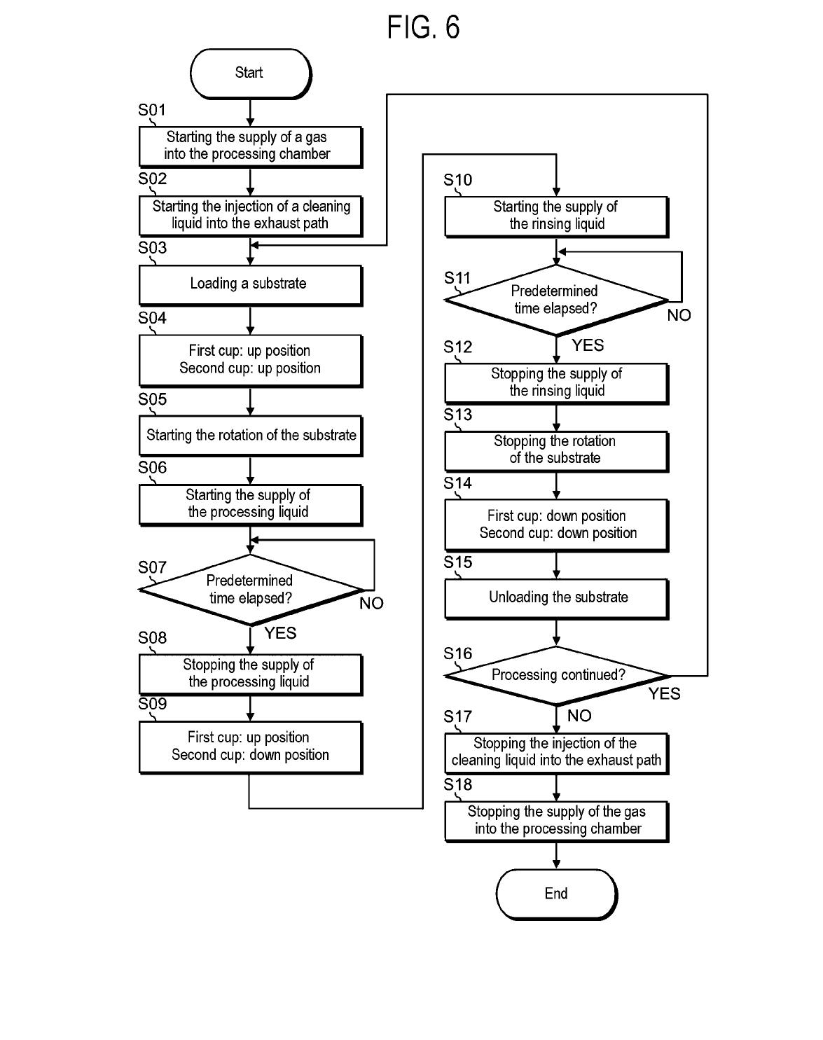

Substrate processing performed by the substrate processing apparatus 1 according to this embodiment will be described using FIG. 6 in addition to FIGS. 1 to 5 above. FIG. 6 is a flowchart illustrating the operation of the substrate processing apparatus 1. Before the substrate processing apparatus 1 begins operation, the holders 12 are at the release position, and the first cup 41 and the second cup 42 are positioned at the down position. Furthermore, the nozzle 21 of the processing liquid supply part 20 and the nozzle 31 of the rinsing liquid supply part 30 are positioned at the retracted position.

First, when the operation of the substrate processing apparatus 1 is started, the control device 90 controls the gas supply part 60 to supply a clean gas into the processing chamber 50 (step S01). When the gas is supplied into the processing chamber 50 and is pushed out, the interior of the processing chamber 50 is evacuated. As described above, the gas supplied into the processing space flows to the communication portion 730 through the gas flow path 47 or the through-holes 55b formed in the intermediate plate 55. The gas then flows from the communication portion 730 to the first exhaust path 710 or the second exhaust path 720 and is discharged to the outside of the substrate processing apparatus 1 through the first exhaust port 71a or the second exhaust port 72a.

Next, the control device 90 controls the removal part 80 to start injecting the mist-like cleaning liquid from the first nozzle 81 and the second nozzle 82 (step S02). Injecting the cleaning liquid from the first nozzle 81 creates a state in which mist is present in a region below the first exhaust port 71a in the first exhaust path 710. Furthermore, injecting the cleaning liquid from the second nozzle 82 creates a state in which mist is present in a region below the second exhaust port 72a in the second exhaust path 720. The supplied mist-like processing liquid falls due to the injection force and the gravity, and is discharged as a liquid from the discharge port 73a formed in the bottom plate 73 to the outside of the substrate processing apparatus 1.

Next, the substrate W to be processed is loaded into the processing chamber 50 v the loading/unloading port 54a (step S03). The loaded substrate W is held by the holders 12 moving to the holding position.

Once the substrate W is held, the control device 90 controls the first lifting mechanism 45 to move the first cup 41 to the up position, and controls the second lifting mechanism 46 to move the second cup 42 to the up position (step S04).

When the first cup 41 and the second cup 42 move to the up position, the control device 90 controls the rotational drive part 13 to start rotating the rotary table 11. The rotation of the rotary table 11 rotates the substrate W held by the holders 12 (step S05).

Next, the control device 90 controls the processing liquid supply part 20 to start supplying the processing liquid to the substrate W held by the holders 12 (step S06). Under the control of the control device 90, the processing liquid supply part 20 operates the swing mechanism 23 to swing the swing arm 22, thereby moving the nozzle 21 to the injection position facing the vicinity of the center of the substrate W. The processing liquid (SPM) is then injected from the nozzle 21 toward the vicinity of the center of the substrate W. The processing liquid supplied to the substrate W spreads toward the outer peripheral edge of the substrate W due to the rotation of the substrate W, thereby processing the entire upper surface of the substrate W. The processing liquid that reaches the outer peripheral edge of the substrate W splashes from the substrate W and is received by the inner wall of the second cup 42. The processing liquid received on the inner wall of the second cup 42 flows down into the second liquid receiving part 44 and is discharged to the outside of the substrate processing apparatus 1 through the discharge port 440.

At this time, fumes are generated inside the processing chamber 50 as a result of the SPM being injected from the nozzle 21. The fine particles contained in the generated fumes flow, together with the gas (downflow) supplied from the gas supply part 60, toward the first exhaust path 710 or the second exhaust path 720 via the communication portion 730. Since the mist-like cleaning liquid is supplied into the first exhaust path 710 and the second exhaust path 720, the floating fine particles are captured by the mist-like cleaning liquid. The fine particles are then discharged from the discharge port 73a while being contained in the cleaning liquid. This prevents the fine particles, which are generated by the processing liquid, from being contained in the exhaust gas discharged to the outside of the substrate processing apparatus 1 from the first exhaust port 71a and the second exhaust port 72a.

Returning to FIG. 6, when a preset predetermined time has elapsed from the start of supply of the processing liquid to the substrate W (step S07: YES), the control device 90 controls the processing liquid supply part 20 to stop the supply of the processing liquid to the substrate W (step S08). Under the control of the control device 90, the processing liquid supply part 20 stops the injection of the processing liquid from the nozzle 21 and then moves the nozzle 21 to the retracted position.

Next, the control device 90 moves the second cup 42 to the down position by the second lifting mechanism 46 while keeping the first cup 41 at the up position (step S09). With the first cup 41 located at the up position and the second cup 42 located at the down position, the rinsing liquid to be subsequently supplied to the substrate W is splashed from the substrate W and then received by the first cup 41.

When the second cup 42 moves to the down position, the control device 90 controls the rinsing liquid supply part 30 to start supplying the rinsing liquid to the substrate W held by the holders 12 (step S10). Under the control of the control device 90, the rinsing liquid supply part 30 operates the swing mechanism 33 to swing the swing arm 32, thereby moving the nozzle 31 to the injection position facing the vicinity of the center of the substrate W. The rinsing liquid is then discharged from the nozzle 31 toward the vicinity of the center of the substrate W. The rinsing liquid supplied to the substrate W spreads toward the outer peripheral edge of the substrate W as the substrate W rotates, thereby replacing the processing liquid on the substrate W with the rinsing liquid to rinse the entire upper surface of the substrate W. The processing liquid that reaches the outer peripheral edge of the substrate W is splashed from the substrate W and is received by the inner wall of the first cup 41. The processing liquid received by the inner wall of the first cup 41 flows down into the first liquid receiving part 43 and is discharged to the outside of the substrate processing apparatus 1 through the discharge port 430.

When a preset predetermined time has elapsed from the start of supply of the rinsing liquid to the substrate W (step S11: YES), the control device 90 controls the rinsing liquid supply part 30 to stop the supply of the rinsing liquid to the substrate W (step S12). Under the control of the control device 90, the rinsing liquid supply part 30 stops the injection of the rinsing liquid from the nozzle 31 and then moves the nozzle 31 to the retracted position.

When the rinsing process for the substrate W is completed, the control device 90 controls the rotational drive part 13 to stop the rotation of the rotary table 11. This stops the rotation of the substrate held by the holders 12 (step S13). Thereafter, the first cup 41 is moved to the down position (step S14). Then, the substrate W is unloaded from the loading/unloading port 54a (step S15).

The control device 90 determines whether there is a next substrate W to be processed (step S16). If there is a next substrate W to be processed (step S16: YES), the process returns to step S03 and the processing of steps S03 to S15 is performed.

On the other hand, if there is no substrate W to be processed next (step S16: NO), the control device 90 controls the removal part 80 to stop the injection of the mist-like cleaning liquid from the first nozzle 81 and the second nozzle 82 (step S17), and then controls the gas supply part 60 to stop the supply of the clean gas into the processing chamber 50 (step S18), thereby terminating the operation of the substrate processing apparatus 1.

As described above, the substrate processing apparatus 1 according to this embodiment includes a processing chamber 50 configured to define a space for processing a substrate W, a rotary holding part 10 configured to hold and rotate the substrate W, a processing liquid supply part 20 configured to supply a processing liquid to the substrate W held by the rotary holding part 10, an exhaust part 70 having an exhaust path (first exhaust path 710 and second exhaust path 720) for discharging a gas discharged from the inside of the processing chamber 50 to the outside, and a removal part 80 having a nozzle (first nozzle 81 and second nozzle 82), which is arranged inside the exhaust path (first exhaust path 710 and second exhaust path 720) and configured to inject a mist-like cleaning liquid.

According to the substrate processing apparatus 1 of this embodiment, floating particles generated by the supply of the processing liquid from the processing liquid supply part 20 are captured by the mist-like cleaning liquid injected from the first nozzle 81 and the second nozzle 82 of the removal part 80 inside the first exhaust path 710 and the second exhaust path 720. This prevents the particles from being contained in the exhaust gas discharged from the first exhaust port 71a and the second exhaust port 72a to the outside of the substrate processing apparatus 1. Therefore, for example, in an exhaust gas treatment facility into which the exhaust gas discharged from the substrate processing apparatus 1 flows, it is possible to reduce the energy required to detoxify the exhaust gas, reduce the load on the exhaust gas treatment facility, and reduce the frequency of maintenance of the exhaust gas treatment facility.

In addition, the exhaust part 70 has a first exhaust port 71a (second exhaust port 72a) configured to bring the first exhaust path 710 (second exhaust path 720) into communication with the outside, and the first nozzle 81 (second nozzle 82) is provided below the first exhaust port 71a (second exhaust port 72a).

The mist-like cleaning liquid injected from the first nozzle 81 (second nozzle 82) flows downward due to the gravity. Therefore, by providing the first nozzle 81 (second nozzle 82) below the first exhaust port 71a (second exhaust port 72a), the cleaning liquid supplied to the exhaust path can be prevented from being discharged together with the exhaust gas from the first exhaust port 71a (second exhaust port 72a).

In addition, the first exhaust path 710 (second exhaust path 720) has a section in which the flow of the gas passing through the inside of the first exhaust path 710 (second exhaust path 720) flows from bottom to top, and the first nozzle 81 (second nozzle 82) is arranged in the section.

As a result, the direction of gas flow and the direction of gravity acting on the cleaning liquid injected from the first nozzle 81 (second nozzle 82) are opposite to each other. As the cleaning liquid injected from the first nozzle 81 (second nozzle 82) falls downward due to the gravity, it comes into contact with the gas containing fine particles generated by the supply of the processing liquid and can capture the floating fine particles, which makes it possible to efficiently capture the fine particles.

The first nozzle 81 (second nozzle 82) is provided so that the injection direction faces downward, and is configured to inject the cleaning liquid so as to diffuse the cleaning liquid in a circular cone shape.

This makes it easier for the cleaning liquid injected from the first nozzle 81 (second nozzle 82) to be supplied to the inner wall that defines the first exhaust path 710 (second exhaust path 720). In the above-described embodiment, the spray pattern of the cleaning liquid injected from the first nozzle 81 is set so as to contact at least a portion of the first side wall 51 and a portion of the first outer wall 71, and the spray pattern of the cleaning liquid injected from the second nozzle 82 is set so as to contact at least a portion of the second side wall 52 and a portion of the second outer wall 72.

In the processing liquid that generates fumes, the fumes may come into contact with the inner wall of the exhaust path, causing fine particles to adhere to the inner wall. If the fine particles contained in the fumes adhere to and accumulate on the inner wall of the exhaust path, exhaust efficiency will be impaired. According to this embodiment, the cleaning liquid is more easily supplied to the inner wall of the exhaust path. Therefore, the inner wall of the exhaust path becomes wet, making it difficult for fine particles to accumulate. Furthermore, even if fine particles adhere to the inner wall of the exhaust path, they are washed away by the cleaning liquid injected from the first nozzle 81 (second nozzle 82). Therefore, it is possible to prevent a decrease in exhaust efficiency.

### Modifications

Although one embodiment of the present disclosure has been described above, the present disclosure is not limited thereto and various modifications may be made.

(1) The processing liquid supplied by the processing liquid supply part 20 is not limited to the SPM. The processing liquid supplied to the substrate W by the processing liquid supply part 20 may be, for example, hydrofluoric acid (HF), dilute hydrofluoric acid (DHF), buffered hydrofluoric acid (BHF), or a mixture of hydrofluoric and nitric acid (hydrofluoric acid and nitric acid (HNO₃)). The substrate processing apparatus 1 of this embodiment is suitable for processing the substrate W using a processing liquid that generates fumes when supplied to the substrate W.

(2) In the above-described embodiment, there has been described the example in which the first side wall 51, the second side wall 52, the third side wall 53, and the fourth side wall 54 constituting the processing chamber 50 are portions of the first exhaust path 710 and the second exhaust path 720. However, the present disclosure is not limited thereto. The first exhaust path 710 and the second exhaust path 720 may be formed by independent pipes. In addition, the number of exhaust paths may be one, or three or more.

(3) In the above-described embodiment, the supply of the mist-like cleaning liquid to the exhaust paths (first exhaust path 710 and second exhaust path 720) is started before the substrate W is loaded, and is performed until there are no more substrates W to be processed (step S16: NO). However, the timing of starting and stopping the supply of the cleaning liquid is not limited thereto. The control device 90 may control the removal part 80 (first nozzle 81 and second nozzle 82) to inject the cleaning liquid at least while the processing liquid is being supplied from the processing liquid supply part 20 to the substrate W (between steps S06 and S08). Since a large amount of fumes are generated while the processing liquid is being injected from the nozzle 21 of the processing liquid supply part 20, the mist-like cleaning liquid is injected into the exhaust path at least during this period, which makes it possible to prevent fine particles from being contained in the gas discharged to the outside of the substrate processing apparatus 1.

However, it takes a certain amount of time for the gas containing fumes generated in the processing space to reach the exhaust path. Furthermore, even after the supply of the processing liquid from the processing liquid supply part 20 has stopped, new fumes may be generated from the processing liquid adhering to the collection part 40. Therefore, it is preferable to stop the injection of the cleaning liquid from the removal part 80 after a certain amount of time has passed since the supply of the processing liquid from the processing liquid supply part 20 was stopped.

(4) In the above-described embodiment, the temperature of the cleaning liquid injected from the first nozzle 81 and the second nozzle 82 is the room temperature. However, the present disclosure is not limited thereto. For example, a heater may be provided in the pipe connected to the first nozzle 81 and the second nozzle 82 to heat the cleaning liquid flowing through the pipe, and a high-temperature mist-like cleaning liquid may be supplied into the first exhaust path 710 and the second exhaust path 720.

By increasing the temperature of the cleaning liquid supplied into the first exhaust path 710 and the second exhaust path 720, the cleaning performance of the cleaning liquid to wash away fine particles adhering to the inner walls constituting the first exhaust path 710 and the inner walls constituting the second exhaust path 720 is improved.

(5) The removal part 80 may further include a flow rate adjustment part that changes the flow rate of the cleaning liquid injected from the first nozzle 81 and the second nozzle 82. The flow rate adjustment part may be, for example, an air-operated valve that is provided midway along a path connected to the first nozzle 81 and the second nozzle 82 and controlled by the control device 90. The control device 90 may control the flow rate adjustment part so that the flow rate of the cleaning liquid injected from the first nozzle 81 and the second nozzle 82 is higher when the processing liquid supply part 20 is supplying the processing liquid to the substrate W than when the processing liquid supply part 20 is not supplying the processing liquid to the substrate W.

As described above, a large amount of fumes is generated while the processing liquid is being injected from the nozzle 21 of the processing liquid supply part 20. Therefore, by increasing the amount of cleaning liquid supplied to the exhaust path while the processing liquid supply part 20 is supplying the processing liquid, it is possible to make it easier to capture floating fine particles.

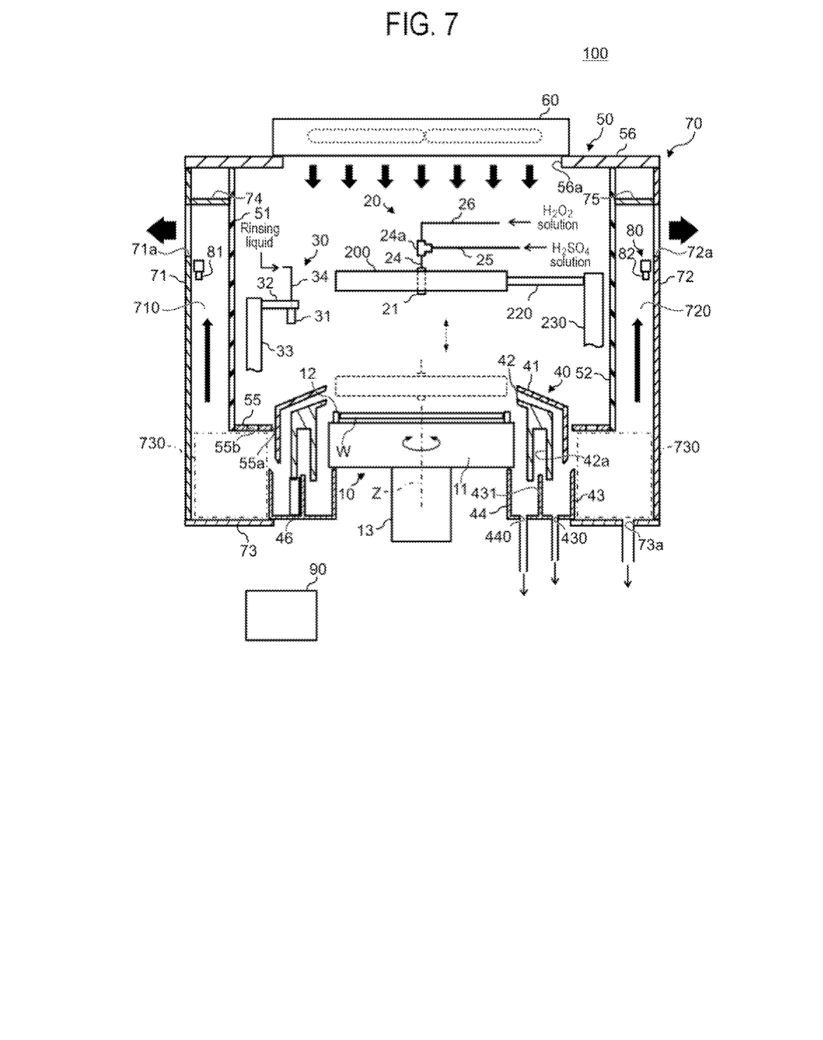

(6) The substrate processing apparatus 1 may include a heating part configured to heat the substrate W to which the processing liquid has been supplied or the processing liquid on the substrate W. FIG. 7 shows an example of the substrate processing apparatus 100 that includes a heating part 200. The heating part 200 has a circular outer shape that is the same as or larger than the substrate W in a plan view. The heating part 200 includes a heater that generates heat when supplied with power, and the drive of the heating part is controlled by the control device 90.

A through-hole through which the nozzle 21 of the processing liquid supply part 20 is inserted is formed at the center of the heating part 200. The heating part 200 is supported by an arm 220 and is provided above the rotary table 11 so as to be movable up and down. One end of the arm 220 is connected to the heating part 200, and the other end of the arm 220 is connected to an elevation drive part 230. The elevation drive part 230 is a drive source that raises and lowers the heating part 200 by raising and lowering the arm 220. The nozzle 21 is raised and lowered together with the heating part 200.

In FIG. 7, the heating part 200 at a remote position spaced apart upward from the substrate W held by the holders 12 is indicated by a solid line, and the heating part 200 at a close position close to the substrate W is indicated by a dashed line. When the processing liquid is injected from the nozzle 21 of the processing liquid supply part 20, the heating part 200 is located at the close position. Then, the substrate W or the processing liquid on the substrate W is heated while the processing liquid is supplied to the substrate W. By heating the substrate W or the processing liquid on the substrate W, the processing rate by the processing liquid increases, and the processing efficiency of the substrate W can be improved.

Although several embodiments of the present disclosure have been described above, these embodiments are presented as examples and are not intended to limit the scope of the present disclosure. These novel embodiments may be embodied in various other forms, and various omissions, substitutions, and modifications may be made without departing from the spirit of the present disclosure. These embodiments and their modifications are included within the scope and spirit of the present disclosure, and are also included in the scope of the present disclosure and its equivalents as defined in the claims.

According to the present disclosure in some embodiments, it is possible to prevent the fine particles from being contained in a gas, which is discharged from a processing chamber for processing a substrate to the outside of the substrate processing apparatus.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A substrate processing apparatus, comprising:
a processing chamber configured to define a space for processing a substrate;
a rotary holding part configured to hold and rotate the substrate;
a processing liquid supply part configured to supply a processing liquid to the substrate held by the rotary holding part;
an exhaust part having an exhaust path for discharging a gas discharged from an interior of the processing chamber to an outside; and
a removal part including a nozzle, which is arranged inside the exhaust path and configured to inject a mist-like cleaning liquid.

2. The substrate processing apparatus of claim 1, wherein the processing liquid supplied to the substrate by the processing liquid supply part is a mixture of a sulfuric acid solution and a hydrogen peroxide solution.

3. The substrate processing apparatus of claim 1, further comprising:
a control device configured to control the processing liquid supply part and the removal part,
wherein the control device controls the nozzle to inject the cleaning liquid at least while the processing liquid is being supplied to the substrate by the processing liquid supply part.

4. The substrate processing apparatus of claim 1, wherein the exhaust path has a section in which the gas passing through an inside of the exhaust path flows from bottom to top, and
wherein the nozzle is arranged in the section.

5. The substrate processing apparatus of claim 1, wherein the exhaust part has an exhaust port configured to bring the exhaust path into communication with the outside, and
wherein the nozzle is provided below the exhaust port.

6. The substrate processing apparatus of claim 5, wherein the nozzle is provided so that an injection direction of the nozzle faces downward, and is configured to inject the cleaning liquid so as to diffuse the cleaning liquid in a circular cone shape.

7. The substrate processing apparatus of claim 1, wherein the exhaust part has an exhaust port configured to bring the exhaust path into communication with the outside,
wherein the exhaust path has a section in which the gas passing through an inside of the exhaust path flows from bottom to top, and
wherein the nozzle is arranged in the section below the exhaust port.

8. The substrate processing apparatus of claim 2, further comprising:
a control device configured to control the processing liquid supply part and the removal part,
wherein the control device controls the nozzle to inject the cleaning liquid at least while the processing liquid is being supplied to the substrate by the processing liquid supply part.

9. The substrate processing apparatus of claim 2, wherein the exhaust path has a section in which the gas passing through an inside of the exhaust path flows from bottom to top, and
wherein the nozzle is arranged in the section.

10. The substrate processing apparatus of claim 2, wherein the exhaust part has an exhaust port configured to bring the exhaust path into communication with the outside, and
wherein the nozzle is provided below the exhaust port.

11. The substrate processing apparatus of claim 10, wherein the nozzle is provided so that an injection direction of the nozzle faces downward, and is configured to inject the cleaning liquid so as to diffuse the cleaning liquid in a circular cone shape.

12. The substrate processing apparatus of claim 2, wherein the exhaust part has an exhaust port configured to bring the exhaust path into communication with the outside,
wherein the exhaust path has a section in which the gas passing through an inside of the exhaust path flows from bottom to top, and
wherein the nozzle is arranged in the section below the exhaust port.

13. The substrate processing apparatus of claim 12, further comprising:
a control device configured to control the processing liquid supply part and the removal part,
wherein the control device controls the nozzle to inject the cleaning liquid at least while the processing liquid is being supplied to the substrate by the processing liquid supply part.

14. The substrate processing apparatus of claim 12, wherein the nozzle is provided so that an injection direction of the nozzle faces downward, and is configured to inject the cleaning liquid so as to diffuse the cleaning liquid in a circular cone shape.
